(19) United States
(12) Patent Application Publication
(10) Pub. No.: US 2025/0112029 A1
(43) Pub. Date: Apr. 3, 2025

(54) SUPPRESSING HEATING OF A PLASMA PROCESSING CHAMBER LID

(71) Applicant: Applied Materials, Inc., Santa Clara, CA (US)

(72) Inventors: Alvaro Garcia de Gorordo, Austin, TX (US); Michael T. Nichols, Eden Prairie, MN (US); Shreeram Dash, Newark, CA (US)

(21) Appl. No.: 18/479,555

(22) Filed: Oct. 2, 2023

(51) Int. Cl. H01J 37/32

(52) U.S. Cl. CPC H01J 37/32522; H01J 37/321; H01J 37/32146; H01J 37/3266; H01J 2237/334

(57) ABSTRACT

Semiconductor processing systems and system components are described for mitigating lid heating of a plasma processing chamber. One system includes a plasma-based processing chamber enclosing a processing region, the processing chamber comprising a first portion including sidewalls and a bottom and a second portion including a chamber lid; a substate support within the processing chamber and configured to retain a first substrate in the processing region of the chamber; an inductively coupled plasma source configured to direct RF energy into the chamber; a conductive structure proximate to the chamber lid on an exterior side of the processing chamber; and a power source configured to apply a negative charge to the conductive structure that generates an electric field through the chamber lid, the electric filed providing repulsion force to incident electrons.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched.

### SUMMARY

This specification describes technologies for reducing lid heating during operation of a plasma processing chamber of a plasma-based processing system. A plasma-based processing system generates a plasma within a processing region to perform a particular process, e.g., plasma etching of a substrate supported within the processing chamber. As increasingly higher voltage biases are used to perform particular processing operations, the lid of the chamber incurs greater heating. This heating of the chamber lid may be caused, for example, by impacts on the lid of electrons emitted from the surface of a substrate being processed in the chamber. Excessive heating can lead to damage to the chamber lid.

To reduce lid heating, techniques are provided for reducing particle impacts on the chamber lid during a plasma-based processing operation. In some implementations, a voltage is applied to a conductive structure on an outer side of the chamber lid, i.e., opposite the interior of the plasma chamber. The resulting electric field can deflect charged electrons away from the lid surface. In some other implementations, a magnetic field is applied to at least a region of the plasma chamber to deflect electrons away from the lid surface.

In general, one innovative aspect of the subject matter described in this specification can be embodied in a system. The system includes a plasma-based processing chamber enclosing a processing region, the processing chamber including a first portion including sidewalls and a bottom and a second portion including a chamber lid; a substate support within the processing chamber and configured to retain a first substrate in the processing region of the chamber; an inductively coupled plasma source configured to direct RF energy into the chamber; a conductive structure proximate to the chamber lid on an exterior side of the processing chamber; and a power source configured to apply a negative charge to the conductive structure that generates an electric field through the chamber lid that provides a repulsion force to incident electrons.

In general, another innovative aspect of the subject matter described in this specification can be embodied in a system. The system includes a plasma-based processing chamber enclosing a processing region, the processing chamber including a first portion including sidewalls and a bottom and a second portion including a chamber lid; a substate support within the processing chamber and configured to retain a first substrate in the processing region of the chamber; an inductively coupled plasma source configured to direct RF energy into the chamber; and a magnetic field source configured to provide a magnetic field to a region of the processing chamber that is configured to deflect electrons emitted from the substrate.

In general, another innovative aspect of the subject matter described in this specification can be embodied in a method of mitigating lid heating during operation of a plasma processing chamber. The method includes igniting a plasma within the plasma processing chamber; applying bias voltage to substate support to attract ions from the plasma; and applying an electrical or magnetic field to deflect electrons emitted from the substrate away from a lid of the plasma processing chamber.

The subject matter described in this specification can be implemented in these and other embodiments so as to realize one or more of the following advantages. The chamber lid heating is mitigated at the source rather than managing the heat through cooling structures such as cooling fans or circulating heat transfer fluid. Additionally, by targeting the source of the heating and thereby reducing the heating, the risk of being unable to keep up with cooling at increasingly higher bias voltages through conventional cooling techniques, such as cooling fans, is reduced.

Although the remaining disclosure will describe the innovative technologies in the context of a particular type of plasma-based processing chamber using the disclosed technology, it will be readily understood that the systems and methods may be applicable to a variety of other types of plasma-based substrate processing chambers. Accordingly, the technology should not be considered to be so limited as for use with the described etch-based processing alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example processing chamber.

FIG. 2 shows a schematic cross-sectional view of an example processing chamber that illustrates lid heating.

FIG. 3 shows a schematic cross-sectional view of an example processing chamber using a pulsed voltage at the chamber lid.

FIG. 4 shows a schematic cross-sectional view of another example processing chamber using a pulsed voltage at the chamber lid.

FIG. 5 shows a schematic cross-sectional view of an example processing chamber using a constant voltage at the chamber lid.

FIG. 6 shows a schematic cross-sectional view of an example processing chamber using an applied magnetic field to deflect electrons from the chamber lid.

FIG. 7 shows a schematic cross-sectional view of another example processing chamber using an applied magnetic field to deflect electrons from the chamber lid.

FIG. 8 shows a schematic cross-sectional view of another example processing chamber using an applied magnetic field to deflect electrons from the chamber lid.

FIG. 9 shows a flow diagram of an example process for deflecting electrons from a chamber lid.

Like reference numbers and designations in the various drawings indicate like elements.

### DETAILED DESCRIPTION

The present specification describes technologies configured to reduce or eliminate heating of a plasma chamber lid caused by particle impacts. In particular, during operation of a plasma based processing system, electrons can be emitted from a surface of a substrate being processed and directed towards the chamber lid. These cumulative particle impacts can have a heating effect on the chamber lid. The technologies described in this specification apply electrostatic or magnetic fields to regions of the plasma chamber to deflect electrons to reduce the number of particle impacts on the chamber lid.

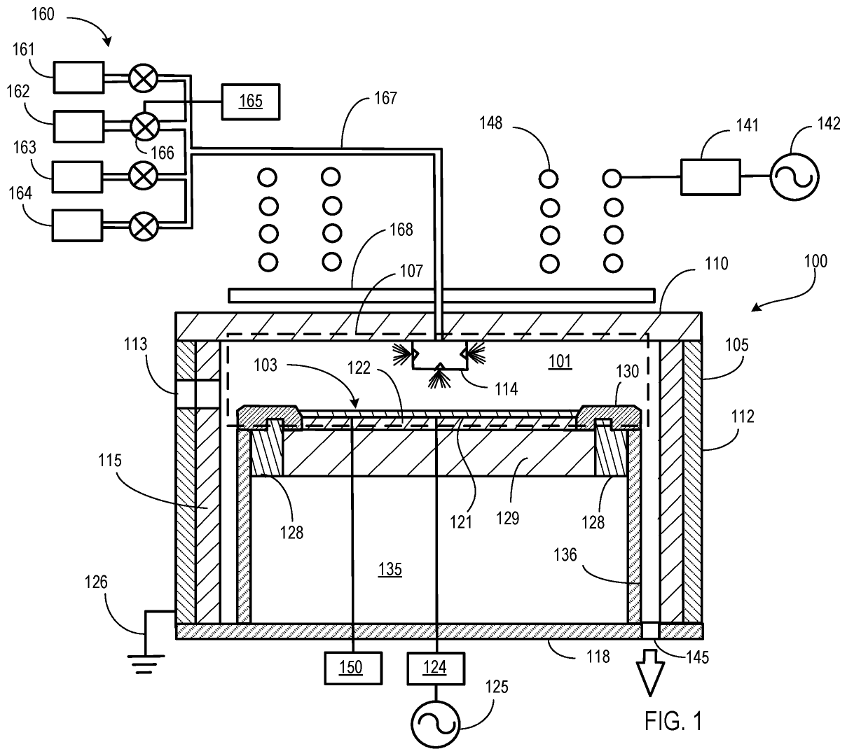

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. The chamber lid 110 can be formed from a dielectric material that allows for passage of energy from an inductively coupled plasma (ICP) source through the chamber lid 110 to the processing volume 101. In some instances, the chamber lid 110 is referred to as a dielectric window.

A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more vacuum pumps and throttle valves that output gasses and processing byproducts to a foreline vent.

The chamber 100 can also include a lid heater 168 disposed on the outer side of the chamber lid 110 opposite the chamber volume 101. In particular, the lid heater 168 can be positioned between the chamber lid 110 and coils 148 of an inductively coupled plasma source. The lid heater 168 can be used to provide a set chamber temperature before initiating a plasma processing operation. In some implementations, the lid heater 168 includes or is proximate to a shielding material, e.g., Faraday shield, placed between the lid heater 168 and the chamber lid 110. The shielding material reduces radio frequency coupling between the ICP source to the lid heater 168. The lid heater 168, with shielding, can be configured with openings to allow for coupling of the ICP source energy to the chamber volume 101.

In some implementations, the heater 168 includes one or more heating elements, e.g., resistive heating elements, coupled to a power supply (not shown) configured to provide sufficient energy to control the temperature of the heater 168, for example, to be between 50 and 100 degrees Celsius. The heater 168 can be electrically grounded, e.g., to the sidewalls of the chamber 100 or floating, e.g., may be positioned without being electrically coupled to ground.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ESC 122 and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves and other components to control the flow of the process gases from the sources. Valves 166 can control the flow of the process gases from the gas sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers.

The lid 110 can incorporate a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna such as one or more inductor coils 148 can be provided adjacent to the plasma processing chamber 100. An antenna power supply 142 can power the inductor coils 148 through a match circuit 141 to inductively couple energy, such as RF energy, to the process gas to maintain a plasma formed from the process gas in the chamber volume 101 of the plasma processing chamber 100. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

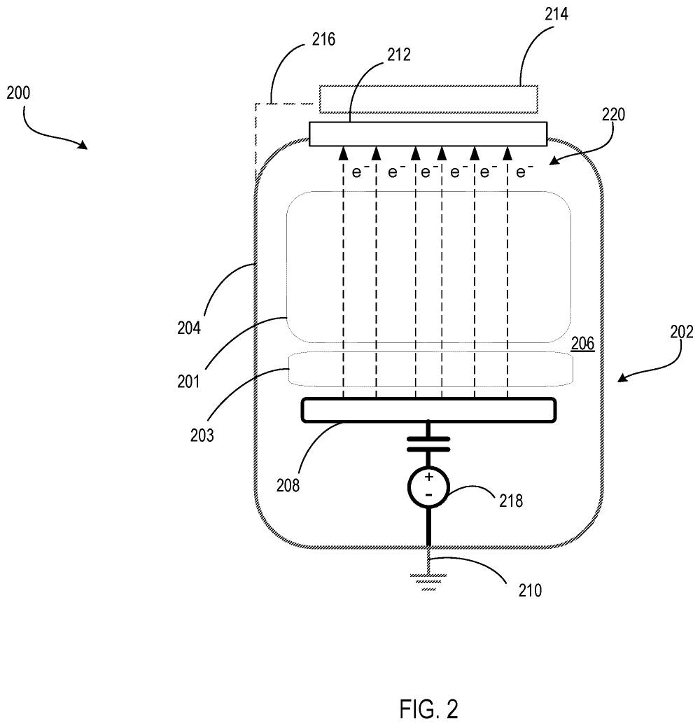

FIG. 2 shows a schematic cross-sectional view 200 of an example processing chamber 202 that illustrates lid heating. In particular, the processing chamber 200 illustrates a simplified version of a portion of processing chamber 100 shown in FIG. 1. The cross-sectional view 200 includes chamber body 204 defining a chamber volume 206 in which a substrate 208 can be processed. The chamber body 204 includes sidewalls and a bottom which are coupled to a ground 210. The chamber body 204 supports a chamber lid 212 to enclose the chamber volume 206. The cross-sectional view 200 also includes a lid heater 214 positioned adjacent to the chamber lid 212 on the exterior side of the chamber volume 206. The lid heater 214 can be floating or grounded, e.g., by being electrically coupled 216 to the chamber body 204.

The lid heater 214 is configured to heat the chamber volume 206 to a particular operating temperature for a plasma processing operation. For example, the lid heater can be configured to heat the chamber volume 206 to substantially 90 degrees Celsius.

The chamber lid 212 is formed from a dielectric material, for example, aluminum oxide, quartz, or other types of ceramic material, that do not impede RF energy generated by the inductively coupled plasma coils (not shown in FIG. 2).

In some implementations, during a plasma processing operation, radio frequency energy is applied to the inductively coupled plasma coils and a particular etch gas mixture is provided to the processing chamber 202. An inductively coupled plasma (represented by region 201) of the etch gas mixture is ignited within the chamber body 204. The inductively coupled plasma source power controls a plasma density formed within the chamber body.

A bias voltage is applied to an electrostatic chuck holding the substrate 208. The bias voltage power controls voltage between the substrate 208 and the plasma 201. This voltage at the plasma-substrate interface is referred to as a sheath (represented by region 203). Ions generated from the plasma are accelerated through the sheath to the substrate 208. The sheath is controlled by the application of the bias voltage to control both the energy and directionality of ions e.g., to direct ions of a particular energy vertically toward the substrate surface to perform etching of layers on the substrate to form various structures. In particular, etching of high aspect ratio features requires higher bias voltages.

As shown in FIG. 2, the bias voltage is generated using a pulse generator 218 that applies voltage pulses to an electrode within the electrostatic chuck supporting the substrate 208. The applied voltage pulses provide a bias that attracts plasma ions, formed from the process gases in the chamber volume 206, to the substrate 208 seated on the electrostatic chuck. In some implementations, the pulse generator results in square wave DC pulses at a specified voltage. The pulses result in a formation of the sheath that collapses as ions discharge the applied voltage and that is reformed again with the next pulse. The timescale of the individual pulses can be very small to provide a near constant voltage presence. For example, in some implementations, the period of the pulses is about 2.5 microseconds. This can include, for example, 2 microsecond off and 500 nanoseconds on. Other suitable pulse periods and pulse widths can be used. In some other implementations, the bias voltage is provided by an RF source.

A byproduct of the plasma etching operation can include electrons 220 emitted from the surface of the wafer. The bias voltage applied to the wafer results in a floating potential at the electrically grounded chamber lid 212. The electrons 220, because of the voltages applied to the chamber 202, are generally flowing from the surface of the wafer 208 to the chamber lid 212. The effect of the electrons incident on the chamber lid 212 is to further heat the chamber lid 212. Different applications require different bias voltage levels. The higher the voltage levels used, e.g., for etching higher aspect ratio features, the more lid heating occurs. Thus, the higher voltage levels may cause an increase in electrons being emitted from the surface of the substrate, or the emitted electrons may have higher energies, or both.

In some cases, lid heating is mitigated by cooling structures outside of the chamber body 204, for example, cooling fans directed at the chamber lid 212. However, as higher voltages are applied for particular plasma processing operations requiring higher aspect ratios, the cooling provided by external fans can be limited. Excessive heating of the chamber lid 212 can result in a decreased lifespan of the chamber lid 212, cracking, or other damage including loss of vacuum within the chamber.

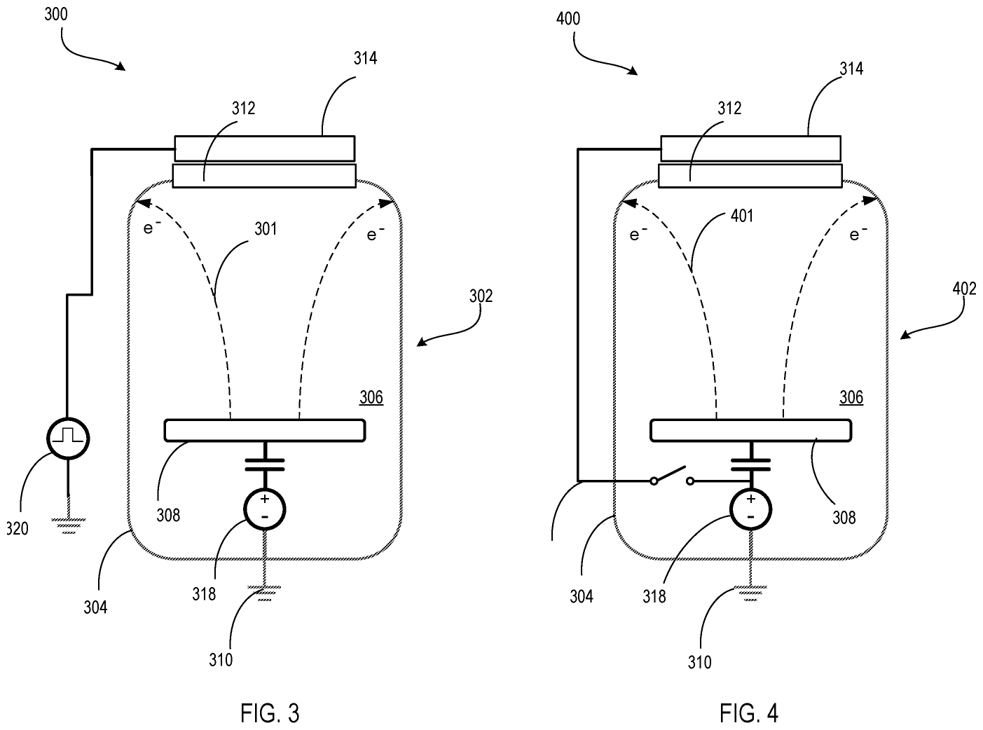

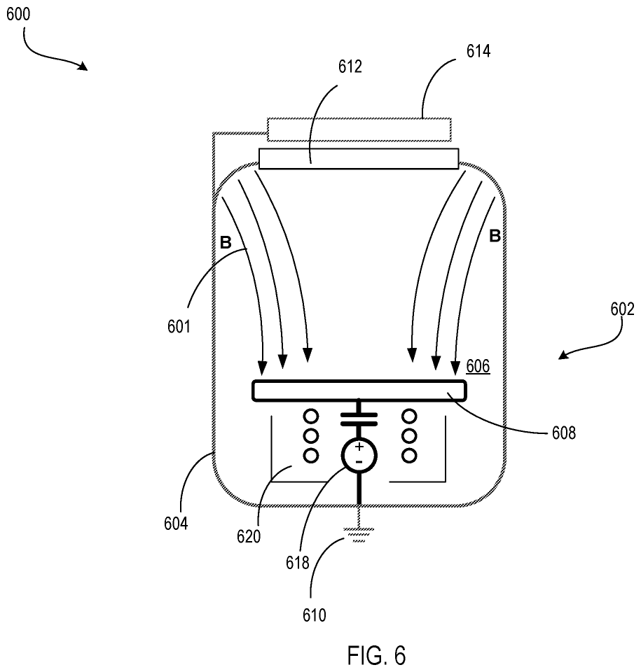

Rather than attempting only to mitigate the heating by applying external cooling to the lid, this specification describes techniques as illustrated in FIGS. 3-8 to suppress the heating itself by redirecting the electrons from impacting the lid surface. FIGS. 3-5 illustrate techniques for applying a bias voltage to the chamber lid to repel electrons emitted from the substrate surface. FIGS. 6-8 illustrate techniques for using magnetic fields to “move” electrons emitted from the substrate surface.

FIG. 3 shows a schematic cross-sectional view 300 of an example processing chamber 302 using a pulsed voltage at the chamber lid. The cross-sectional view 300 includes chamber body 304 defining a chamber volume 306 in which a substrate 308 can be processed. The chamber body 304 includes sidewalls and a bottom which are coupled to a ground 310. The chamber body 304 supports a chamber lid 312 to enclose the chamber volume 206. The cross-sectional view 300 also includes a lid heater 314 positioned adjacent to the chamber lid 312 on the exterior side of the chamber volume 306.

The chamber lid 312 is formed from a dielectric material, for example, a ceramic material, that does not impede RF energy generated by the inductively coupled plasma coils (not shown in FIG. 3).

During operation, a pulse generator 318 applies voltage pulses that create a bias voltage drawing plasma ions to the substrate 308. In some implementations, the voltage pulses can be substantially on the order of 2000V. However, the voltage level can vary depending on the particular operations being performed in the chamber. For example, different plasma etch processes and different aspect ratios can require different bias voltage levels.

The lid heater 314 is configured to heat the chamber volume 306 to a particular operating temperature for a plasma processing operation. For example, the lid heater can be configured to heat the chamber volume 306 to substantially 90 degrees Celsius.

The lid heater 314 is coupled to a pulse generator 320 distinct from the pulse generator 318. The pulse generator 320 applies voltage pulses to the lid heater 314 to create a negative charge. In particular, the pulses are provided on a short timescale such that there is a near constant charge on the lid heater that isn't diminished or neutralized due to particle interactions. In some implementations, the voltage pulses provided by pulse generator 320 are substantially similar to the voltage pulses provided by pulse generator 318, e.g., substantially 2000V. In some implementations, the voltage pulses generated by pulse generator 320 can have a voltage within the range of 1 kV to 10 kV. Some implementations square wave pulses or sawtooth wave pulses. In other implementations, a ramped or RF sinusoidal waveform may be used to generate the negatively charged lid heater 314.

The negatively charged lid heater 314 generates an electric field extending into the plasma chamber through the dielectric lid 312. The electric field from a negatively charged source generates a repulsive force on the electrons 301 emitted from the substrate 308. The repulsive force deflects the electrons 301 from their straight line path from the substrate 308 reducing the number of electrons impacting the lid 312. Reducing the amount of electron impacts on the lid 312 reduces the electron based heating of the lid 312.

FIG. 4 shows a schematic cross-sectional view 400 of an example processing chamber 402 using a pulsed voltage at the chamber lid. The cross-sectional view 400 includes the chamber body 304 defining the chamber volume 306 in which the substrate 308 can be processed. The chamber body 304 supports the chamber lid 312 to enclose the chamber volume 306. The cross-sectional view 400 also includes a lid heater 314 positioned adjacent to the chamber lid 312 on the exterior side of the chamber volume 306.

However, in the example shown in FIG. 4, instead of separate pulse generators, the lid heater 314 is electrically coupled to the pulse generator 318 that provides the bias voltage to the substrate 308. In this example, the magnitude and occurrence of the voltage pulses are synchronized and the need for a separate second pulse generator is eliminated.

Similar to FIG. 3, the lid heater 314 becomes negatively charged to generate an electric field extending into the plasma chamber through the dielectric lid 312. The electric field from a negatively charged source generates a repulsive force on the electrons 401 emitted from the substrate 308. The repulsive force deflects the electrons 401 from their straight line path from the substrate 308 reducing the number of electrons impacting the lid 312.

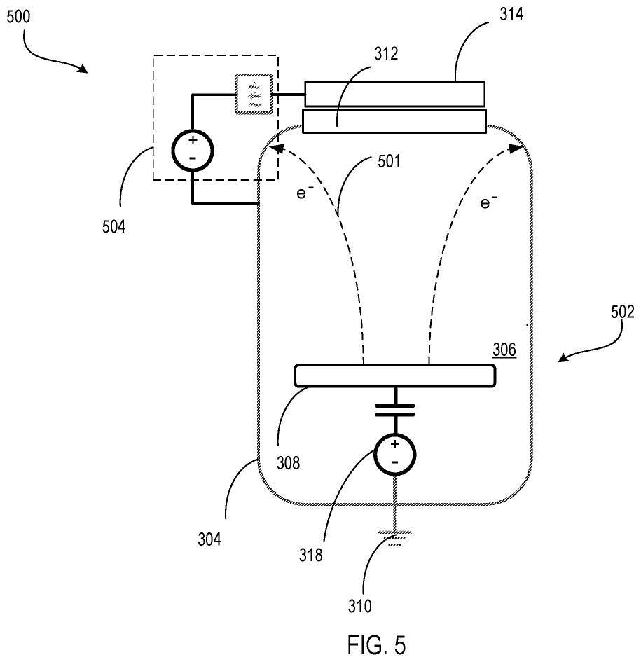

FIG. 5 shows a schematic cross-sectional view 500 of an example processing chamber 502 using a constant voltage at the chamber lid. The cross-sectional view 500 includes the chamber body 304 defining the chamber volume 306 in which the substrate 308 can be processed. The chamber body 304 supports the chamber lid 312 to enclose the chamber volume 306. The cross-sectional view 500 also includes a lid heater 314 positioned adjacent to the chamber lid 312 on the exterior side of the chamber volume 306.

In the example shown in FIG. 5, the lid 314 is biased based on a constant negative DC voltage provided by a DC power source 504. The power source 504 can include a power supply electrically coupled to the lid 314 and grounded to the chamber body 304. The power source 504 can include an inverter that allows for a negative voltage to be applied to the lid heater.

Similar to FIGS. 3-4, the lid heater 314 becomes negatively charged to generate an electric field extending into the plasma chamber through the dielectric lid 312. The electric field from a negatively charged source generates a repulsive force on the electrons 501 emitted from the substrate 308. The repulsive force deflects the electrons 501 from their straight line path from the substrate 308 reducing the number of electrons impacting the lid 312.

FIG. 6 shows a schematic cross-sectional view of an example processing chamber 602 using an applied magnetic field to deflect electrons from the chamber lid. The cross-sectional view 600 includes chamber body 604 defining a chamber volume 606 in which a substrate 608 can be processed. The chamber body 604 includes sidewalls and a bottom which are coupled to a ground 610. The chamber body 604 supports a chamber lid 612 to enclose the chamber volume 606. The cross-sectional view 600 also includes a lid heater 614 positioned adjacent to the chamber lid 612 on the exterior side of the chamber volume 606.

The chamber lid 612 is formed from a dielectric material, for example, a ceramic material, that does not impede RF energy generated by the inductively coupled plasma coils (not shown in FIG. 6).

During operation, a pulse generator 618 applies voltage pulses that create a bias voltage drawing plasma ions to the substrate 608. In some implementations, the voltage pulses can be substantially on the order of 2000V. However, the voltage level can vary depending on the particular operations being performed in the chamber. For example, different plasma etch processes and different aspect ratios can require different bias voltage levels. The magnitude of the voltage pulses can be proportional to the amount of electrons emitted from the surface of the substrate 608 during a plasma processing operation.

A magnetic field B 601 is generated by passing energy, e.g., a current, through coil 620, e.g., a solenoid, positioned within the chamber body between the substrate 608 and the chamber bottom. In particular, the magnetic field is generated so that the electrons emitted from the surface of the substrate are deflected toward the sidewalls of the chamber body 604. In particular, based on the orientation of the coil relative to the surface of the substrate 608, e.g., with central axis perpendicular to a surface of the substrate 608, electrons emitted perpendicular to the substrate surface and directed toward the lid 612 will be deflected toward a helical path based on the magnetic field lines that in many instances may cause the electrons to intersect with the walls of the chamber body.

The force of the deflection depends on the magnetic field strength, the charge of the electron, the velocity of the electron, and the orientation of the magnetic field relative to emitted electrons. Consequently, the magnetic field strength needed to obtain a deflection force that results in the electrons hitting the side walls of the chamber, i.e., a minimum Lamor's, or cyclotron, radius, can be mathematically calculated for a known electron charge, e.g., 2500 eV. For example, a magnetic field strength of 100 to 300 gauss can be applied to maintain a cyclotron radius of substantially 1 centimeter for electron energies of 1 keV to 10 keV. Other field strengths can be used for other suitable cyclotron radiuses and other electron energies.

Positioning the coils 620 beneath the substrate and oriented with a central axis perpendicular to a plane of the substrate may also reduce the risk of interference in the plasma processing operation caused by the generated magnetic field.

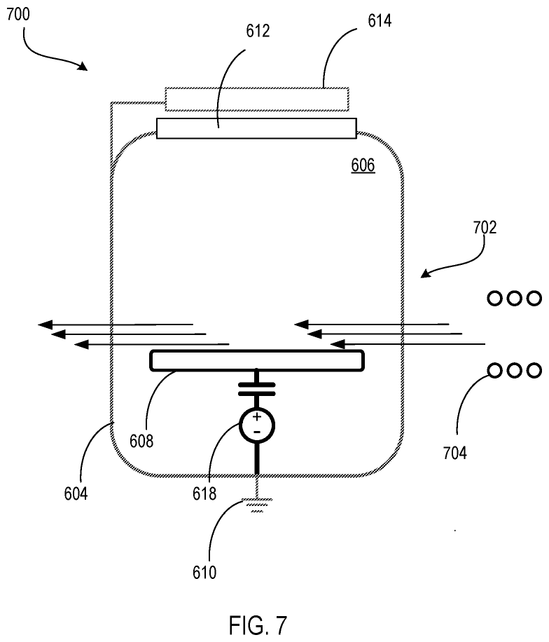

FIG. 7 shows a schematic cross-sectional view 700 of another example processing chamber 702 using an applied magnetic field to deflect electrons from the chamber lid.

The cross-sectional view 700 includes the chamber body 604 defining the chamber volume 606 in which the substrate 608 can be processed. The chamber body 604 includes the sidewalls and the bottom which are coupled to the ground 610. The chamber body 604 supports the chamber lid 612 to enclose the chamber volume 606. The cross-sectional view 700 also includes a lid heater 614 positioned adjacent to the chamber lid 612 on the exterior side of the chamber volume 606.

In the example processing chamber 702, a magnetic field is again generated to deflect electrons emitted from the surface of the substrate 608 during a plasma processing operation to reduce the number of impacts on the lid 612, and thereby reduce lid heating caused by electron impacts.

However, in the processing chamber 702 the magnetic field is generated from outside the sidewalls of the chamber body 604. In the example shown in FIG. 7, a coil 704 is positioned on the side of the processing chamber 702 such that generated magnetic field lines are substantially parallel across a surface of the substrate 608. For example, the coil 704 can be positioned in proximity to the electrostatic chuck portion of the chamber body 604 and oriented so that the central axis of the coil 704 is parallel to the surface of the substrate 608. Electrons emitted from the surface of the substrate 608 during a plasma processing operation will be deflected, with sufficient magnetic field strength, toward the sidewalls of the chamber body 604.

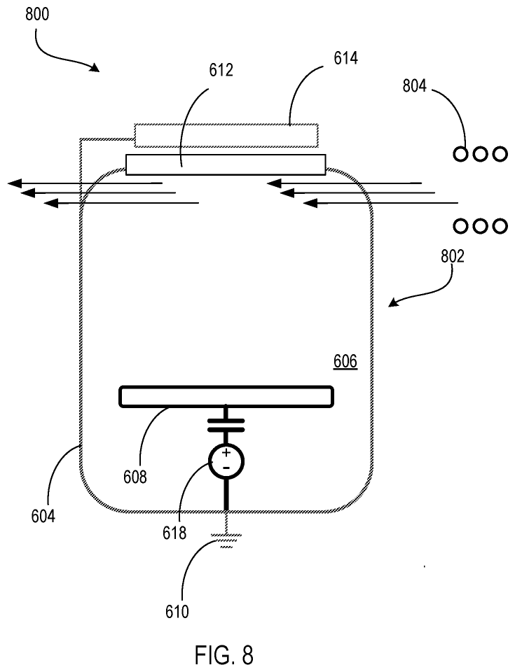

FIG. 8 shows a schematic cross-sectional view 800 of another example processing chamber 802 using an applied magnetic field to deflect electrons from the chamber lid.

The cross-sectional view 800 includes the chamber body 604 defining the chamber volume 606 in which the substrate 608 can be processed. The chamber body 604 includes the sidewalls and the bottom which are coupled to the ground 610. The chamber body 604 supports the chamber lid 612 to enclose the chamber volume 606. The cross-sectional view 800 also includes a lid heater 614 positioned adjacent to the chamber lid 612 on the exterior side of the chamber volume 606.

In the example processing chamber 802, a magnetic field is again generated to deflect electrons emitted from the surface of the substrate 608 during a plasma processing operation to reduce the number of impacts on the lid 612, and thereby reduce lid heating caused by electron impacts.

Similar to the processing chamber 702 illustrated in FIG. 7, in the processing chamber 802 the magnetic field is generated from outside the sidewalls of the chamber body 604. As shown in FIG. 8, a coil 804 is positioned on the side of the processing chamber 802 such that generated magnetic field lines are substantially parallel across a surface of the lid 612. For example, the coil 804 can be positioned in proximity to the upper portion of the chamber near the lid 612 and oriented so that the central axis of the coil 804 is parallel to the surface of the lid 612. Electrons emitted from the surface of the substrate 608 during a plasma processing operation will be deflected, with sufficient magnetic field strength, toward the sidewalls of the chamber body 604, e.g., a magnetic field strength to generate a substantially 1 cm gyroradius.

While in FIGS. 7-8 a coil is illustrated as the source for the generated magnetic field, other suitable sources can be used. For example, magnets on opposite sides of the chamber body can generate a magnetic field between the magnets. In particular, the magnets can have opposite poles facing each other so that the attraction concentrates the magnetic field lines between the two magnets across the chamber body.

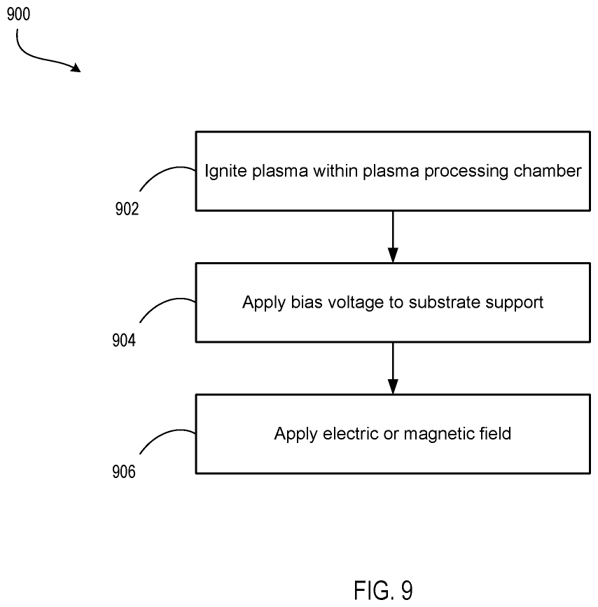

FIG. 9 shows a flow diagram of an example process 900 for deflecting electrons from a chamber lid. For convenience, the process 900 is described with respect to a system that performs the process 900, e.g., a plasma-based processing system.

The system ignites a plasma within a plasma-processing chamber (902). The plasma-processing chamber can be similar to those described above with respect to FIGS. 3-8.

The system applies a bias voltage to a substrate support within the plasma-processing chamber to attract ions from the plasma (904). The bias voltage can be applied by a pulse generator or RF source as described above with respect to FIGS. 1-8.

The system applies an electric or magnetic field to deflect electrons emitted form the substrate away from a lid of the plasma processing chamber (906). A pulse generator can be used to apply an electric field to a conductive region proximate to the lid as described above with respect to FIGS. 3-5. A magnetic field source can be used to generate a magnetic field as described above with respect to FIGS. 6-8.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system comprising:
a plasma-based processing chamber enclosing a processing region, the processing chamber comprising a first portion including sidewalls and a bottom and a second portion including a chamber lid;
a substate support within the processing chamber and configured to retain a first substrate in the processing region of the processing chamber;
an inductively coupled plasma source configured to direct RF energy into the processing chamber;
a conductive structure proximate to the chamber lid on an exterior side of the processing chamber; and
a power source configured to apply a negative charge to the conductive structure that generates an electric field through the chamber lid, the electric field providing a repulsion force to incident electrons.

2. The system of claim 1, wherein the power source is a pulse generator that generates DC pulses of a specified voltage and period.

3. The system of claim 2, wherein the pulse generator generates square wave pulses or sawtooth wave pulses of a negative DC voltage.

4. The system of claim 1, wherein substrate support has a bias voltage applied by a second pulse generator to attract ions to the substrate and wherein the pulse generator applies a voltage corresponding to the bias voltage applied by the second pulse generator voltage.

5. The system of claim 1, wherein the power source is a pulse generator that provides concurrent DC pulses to both the conductive structure and to the substrate support.

6. The system of claim 1, wherein the conductive structure is a lid heater.

7. The system of claim 1, wherein the power source applies the negative charge using ramped or RF power.

8. The system of claim 1, wherein the power source provides constant voltage to the conductive structure.

9. A system comprising:
a plasma-based processing chamber enclosing a processing region, the processing chamber comprising a first portion including sidewalls and a bottom and a second portion including a chamber lid;
a substate support within the processing chamber and configured to retain a first substrate in the processing region of the processing chamber;
an inductively coupled plasma source configured to direct RF energy into the processing chamber; and
a magnetic field source configured to provide a magnetic field to a region of the processing chamber, the magnetic field being configured to deflect electrons emitted from the substrate.

10. The system of claim 9, wherein the magnetic field source is a coil between the substrate and the bottom of the processing chamber, and wherein the coil is oriented with a central axis perpendicular to a planar surface of the substrate.

11. The system of claim 10, wherein the magnetic field source comprises a solenoid.

12. The system of claim 10, wherein magnetic field source comprises one or more magnets.

13. The system of claim 9, wherein the magnetic field source is positioned adjacent to a sidewall of the plasma-based processing chamber in proximity to the substrate.

14. The system of claim 9, wherein the magnetic field source is positioned adjacent to a sidewall of the plasma-based processing chamber in proximity to the chamber lid.

15. A method of mitigating lid heating during operation of a plasma processing chamber comprising:
igniting a plasma within the plasma processing chamber;
applying bias voltage to substate support to attract ions from the plasma; and
applying an electrical or magnetic field to at least a portion of the plasma processing chamber to deflect electrons emitted from the substrate away from a lid of the plasma processing chamber.

16. The method of claim 15, wherein applying an electric or magnetic field comprises applying a negative bias voltage to a conductive structure proximate to the lid and outside of the plasma processing chamber to generate an electric field.

17. The method of claim 15, wherein applying an electric or magnetic field comprises generating a magnetic field using a solenoid positioned beneath the substrate and oriented to deflect electrons along radius with sufficient magnitude to cause electrons to impact sidewalls

18. The method of claim 15, wherein applying an electric or magnetic field comprises generating a magnetic field using a magnetic field source outside of the plasma processing chamber.

19. The method of claim 18, wherein the magnetic field source is positioned adjacent to a sidewall of the plasma-based processing chamber in proximity to the substrate.

20. The method of claim 18, wherein the magnetic field source is positioned adjacent to a sidewall of the plasma-based processing chamber in proximity to the chamber lid.
